(19) United States
(12) Patent Application Publication
(10) Pub. No.: US 2026/0029475 A1
(43) Pub. Date: Jan. 29, 2026

(54) SYSTEMS, APPARATUSES, AND METHODS FOR BATTERY GROUND MONITORING

(71) Applicant: Commonwealth Edison Company, Chicago, IL (US)

(72) Inventors: Donato Martino, Chicago, IL (US); Ramon Jimenez, Chicago, IL (US); Tim Qualls, Chicago, IL (US); Ryan Schiller, Chicago, IL (US); Joseph Rodriguez, Chicago, IL (US); Travis Sauers, Chicago, IL (US); Brian Tracy, Chicago, IL (US)

(21) Appl. No.: 18/958,806

(22) Filed: Nov. 25, 2024

Related U.S. Application Data
(60) Provisional application No. 63/674,440, filed on Jul. 23, 2024.

(51) Int. Cl. G01R 31/3835; G01R 31/389

(52) U.S. Cl. CPC G01R 31/3835; G01R 31/389

(57) ABSTRACT

An apparatus may include a controller and a relay device for measuring voltages associated with a battery and determining resistances associated with the battery that can be used to determine whether there is a battery ground associated with the battery. The relay device may comprise one or more switches that may be coupled to the battery for measuring the voltages. The relay device may be configured to implement an automated configuration sequence of one or more configurations of the one or more switches in order to the measure voltages. The controller may determine resistance values based on the measured voltages values. Based on comparing the resistance values to a threshold, one or more battery grounds of the battery may be determined and a notification may be output based on the detected one or more battery grounds.

### CROSS REFERENCE TO RELATED PATENT APPLICATION

This application claims priority to U.S. Provisional Application No. 63/674,440, filed Jul. 23, 2024, which is herein incorporated by reference in its entirety.

### BACKGROUND

DC battery grounds are undesirable occurrences that can lead to system malfunctions and prevent proper operation. They are typically caused by a variety of factors such as water intrusion, mechanical stresses, and wildlife interference. When such grounds occur, they may prevent systems from operating correctly, inhibit switching, and can even lead to inadvertent equipment operation. Conventional battery ground monitoring methods involve manually monitoring each battery, carried out by field personnel checking at the battery charger. Battery grounds are confirmed by using a process that validates the ohmic values and priority of the grounds. Moreover, these conventional methods involving field personnel are prone to fluctuating measurements due to meter inaccuracies, human data input error, etc. Furthermore, the detectors used for detecting battery grounds are prone to several issues: they cannot detect balanced field grounds, they are prone to equipment misoperation, they have difficulty detecting intermittent battery grounds, they are susceptible to voltage suppression, and they do not provide standardized voltage displays across manufacturers for the same battery ground resistances.

### SUMMARY

It is to be understood that both the following general description and the following detailed description are exemplary and explanatory only and are not restrictive.

Methods, apparatuses, and systems for detecting battery grounds are described. A relay device comprising one or more switches may be coupled to a battery under test for measuring voltages based on one or more configurations of the one or more switches. The relay device may be configured to implement an automated configuration sequence of the one or more configurations in order to measure voltages associated with the battery under test. A controller may be configured to determine resistance values based on the measured values of the voltages. Based on comparing the resistance values to a threshold, one or more battery grounds of the battery under test may be determined and a notification may be output based on the detected one or more battery grounds.

In an embodiment, are apparatuses comprising a relay device comprising one or more switches coupled to a battery under test, wherein the relay device is configured to determine, based on a first configuration of the one or more switches, a value of the first voltage associated with the battery under test, determine, based on a second configuration of the one or more switches, a value of the second voltage associated with the battery under test, determine, based on a third configuration of the one or more switches, a value of the third voltage associated with the battery under test, and send data indicative of the value of the first voltage, the value of the second voltage, and the value of the third voltage, and a controller in communication with the relay device, wherein the controller is configured to receive data indicative of the value of the first voltage, the value of the second voltage, and the value of the third voltage, determine, based on the value of the first voltage and the value of the second voltage and the value of the third voltage, a value of a first resistance associated with the battery under test and a value of a second resistance associated with the battery under test, and cause, based on at least one of the value of the first resistance or the value of the second resistance, output of at least one notification.

In an embodiment, are methods comprising determining, by a relay device, based on a first configuration of one or more switches of the relay device coupled to a battery under test, a value of a first voltage associated with the battery under test, determining, based on a second configuration of the one or more switches, a value of a second voltage associated with the battery under test, determining, based on a third configuration of the one or more switches, a value of a third voltage associated with the battery under test, and sending, to a computing device, data indicative of the value of the first voltage, the value of the second voltage, and the value of the third voltage, wherein the computing device outputs at least one notification based on the value of the first voltage, the value of the second voltage, and the value of the third voltage.

This summary is not intended to identify critical or essential features of the disclosure, but merely to summarize certain features and variations thereof. Other details and features will be described in the sections that follow.

### BRIEF DESCRIPTION OF THE DRAWINGS

In order to provide understanding techniques described, the figures provide non-limiting examples in accordance with one or more implementations of the present disclosure, in which:

FIG. 1 shows an example battery ground detection system;

FIG. 2 shows an example configuration of a relay device;

FIGS. 3A-3C show example configurations of measurement methodology;

FIG. 4 shows an example battery ground scenario;

FIG. 5 shows an example system environment; and

FIG. 6 shows a flowchart of an example method;

### DETAILED DESCRIPTION

As used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another configuration includes from the one particular value and/or to the other particular value. When values are expressed as approximations, by use of the antecedent “about,” it will be understood that the particular value forms another configuration. It will be further understood that the endpoints of each of the ranges are significant both in relation to the other endpoint, and independently of the other endpoint.

It is understood that when combinations, subsets, interactions, groups, etc. of components are described that, while specific reference of each various individual and collective combinations and permutations of these may not be explicitly described, each is specifically contemplated and described herein. This applies to all parts of this application including, but not limited to, steps in described methods. Thus, if there are a variety of additional steps that may be performed it is understood that each of these additional steps may be performed with any specific configuration or combination of configurations of the described methods.

As will be appreciated by one skilled in the art, hardware, software, or a combination of software and hardware may be implemented. Furthermore, the methods and systems may take the form of a computer program product on a computer-readable storage medium (non-transitory) having processor-executable instructions (e.g., computer software) embodied in the storage medium. Any suitable computer-readable storage medium may be utilized including hard disks, CD-ROMs, optical storage devices, magnetic storage devices, memristors, Non-Volatile Random Access Memory (NVRAM), flash memory, or a combination thereof.

Throughout this application reference is made to block diagrams and flowcharts. It will be understood that each block of the block diagrams and flowcharts, and combinations of blocks in the block diagrams and flowcharts, respectively, may be implemented by processor-executable instructions. These processor-executable instructions may be loaded onto a computer (e.g., a special purpose computer), or other programmable data processing apparatus to produce a machine, such that the processor-executable instructions which execute on the computer or other programmable data processing apparatus create a device for implementing the functions specified in the flowchart block or blocks.

This detailed description may refer to a given entity performing some action. It should be understood that this language may in some cases mean that a system (e.g., a computer) owned and/or controlled by the given entity is actually performing the action.

Blocks of the block diagrams and flowcharts support combinations of devices for performing the specified functions, combinations of steps for performing the specified functions and program instruction means for performing the specified functions. It will also be understood that each block of the block diagrams and flowcharts, and combinations of blocks in the block diagrams and flowcharts, may be implemented by special purpose hardware-based computer systems that perform the specified functions or steps, or combinations of special purpose hardware and computer instructions.

The method steps recited throughout this disclosure may be combined, omitted, rearranged, or otherwise reorganized with any of the figures presented herein and are not intend to be limited to the four corners of each sheet presented.

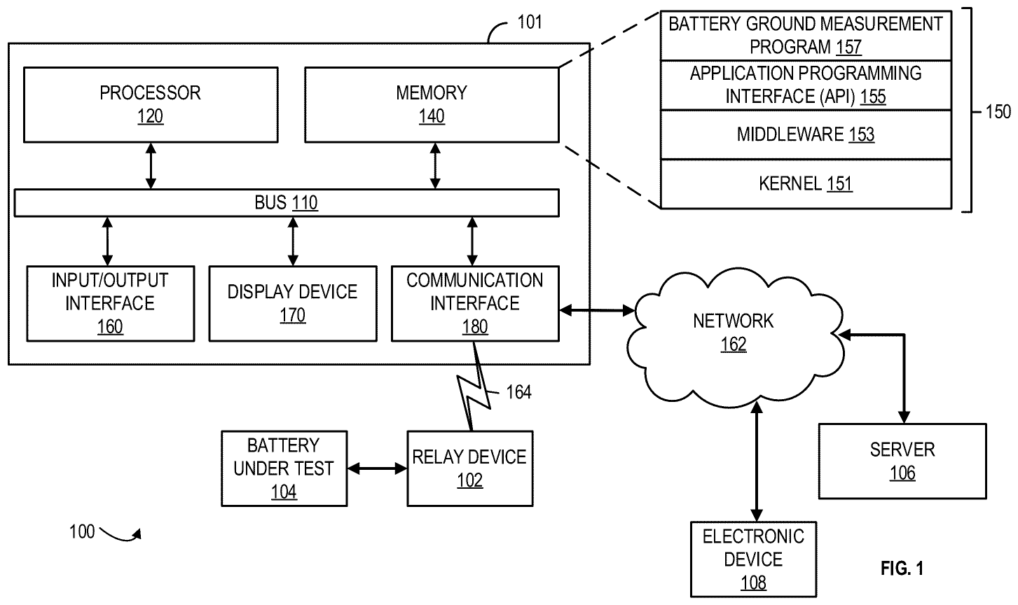

FIG. 1 shows an example system 100 for detecting battery grounds based on a plurality of voltage measurements associated with a plurality of configurations of a relay device coupled to a battery under test. For example, a controller (e.g., controller 101) may be configured to cause one or more switches of a relay device to operate according to a first configuration for measuring a first voltage associated with the battery under test and determine a value of the first voltage. The controller may then cause the one or more switches to operate according to a second configuration for measuring a second voltage associated with the battery under test and determine a value of the second voltage. The controller may then cause the one or more switches to operate according to a third configuration for measuring a third voltage and determine a value of the third voltage. Based on the value of the first voltage, the value of the second voltage, and the value of the third voltage, the controller may determine a value of a first resistance associated with the battery under test and a value of a second resistance associated with the battery under test. The controller may determine whether a battery ground exists for the battery under test based on whether the values for the first resistance and the second resistance satisfy a threshold. The system 100 may include a controller 101 (e.g., a computing device), a relay device 102, a server 106, and an electronic device 108. In an example, the controller 101 may be configured to determine and process a plurality of voltages, received from the relay device 102, associated with a battery under test 104 based on a plurality of configurations of the relay device 102. The controller 101 may be in communication with the server 106 and/or the electronic device 108 via a network (e.g., network 162).

The controller 101 (e.g., computing device) may include a bus 110, one or more processors 120, a memory 140, an input/output interface 160, a display device 170, and a communication interface 180. In certain examples, the controller 101 may omit at least one of the aforementioned elements or may additionally include other elements. The controller 101 may comprise a computing device such as a tablet computer, a laptop computer, a mobile device, a desktop computer, and the like.

The bus 110 may comprise a circuit for connecting the bus 110, the one or more processors 120, the memory 140, the input/output interface 160, the display device 170, and/or the communication interface 180 to each other and for delivering communication (e.g., a control message and/or data) between the bus 110, the one or more processors 120, the memory 140, the input/output interface 160, the display device 170, and/or the communication interface 180.

The one or more processors 120 may include one or more of a Central Processing Unit (CPU), an Application Processor (AP), or a Communication Processor (CP). The one or more processors 120 may control, for example, at least one of the bus 110, the memory 140, the input/output interface 160, the display device 170, and/or the communication interface 180 of the controller 101 and/or may execute an arithmetic operation or data processing for communication. As an example, the one or more processors 120 may implement logic (e.g., hardware, software, firmware, etc.) stored in the memory 140 to cause the controller 101 determine and process a plurality of voltages, received from relay device 102, associated with a battery under test 104 based on a plurality of configurations of the relay device 102. The processing (or controlling) operation of the one or more processors 120 according to various embodiments is described in detail with reference to the following drawings.

The processor-executable instructions executed by the one or more processors 120 may be stored and/or maintained by the memory 140. The memory 140 may include a volatile and/or non-volatile memory. The memory 140 may include random-access memory (RAM), flash memory, solid state or inertial disks, or any combination thereof. As an example, the memory 140 may include an Embedded MultiMedia Card (eMMC). The memory 140 may store, for example, a command or data related to at least one of the bus 110, the one or more processors 120, the memory 140, the input/output interface 160, the display device 170, and/or the communication interface 180 of the controller 101. According to various examples, the memory 140 may store software and/or a program 150 or may comprise firmware. For example, the program 150 may include a kernel 151, a middleware 153, an Application Programming Interface (API) 155, and/or battery ground measurement program 157, and/or the like, configured for controlling one or more functions of the controller 101 and/or an external device (e.g., the relay device 102). At least one part of the kernel 151, middleware 153, or API 155 may be referred to as an Operating System (OS). The memory 140 may include a computer-readable recording medium (e.g., a non-transitory computer-readable medium) having a program recorded therein to perform the methods according to various embodiments by the one or more processors 120. In an example, the voltage measurement values received from the relay device 102, including the resistance values calculated based on the voltage measurement values, may be stored in the memory 140.

The kernel 151 may control or manage, for example, system resources (e.g., the bus 110, the one or more processors 120, the memory 140, etc.) used to execute an operation or function implemented in other programs (e.g., the middleware 153, the API 155, or the battery ground measurement program 157). Further, the kernel 151 may provide an interface capable of controlling or managing the system resources by accessing individual elements of the controller 101 in the middleware 153, the API 155, or the battery ground measurement program 157.

The middleware 153 may perform, for example, a mediation role, so that the API 155, and/or the battery ground measurement program 157 can communicate with the kernel 151 to exchange data. Further, the middleware 153 may handle one or more task requests received from the battery ground measurement program 157 according to a priority. For example, the middleware 153 may assign a priority of using the system resources (e.g., the bus 110, the one or more processors 120, or the memory 140) of the controller 101 to the battery ground measurement program 157. For example, the middleware 153 may process the one or more task requests according to the priority assigned to at least one of the application programs, and thus, may perform scheduling or load balancing on the one or more task requests.

The API 155 may include at least one interface or function (e.g., instruction), for example, for file control, window control, video processing, and/or character control, as an interface capable of controlling a function provided by the battery ground measurement program 157 in the kernel 151 or the middleware 153.

The battery ground measurement program 157 may include logic (e.g., hardware, software, firmware, etc.) that may be implemented to cause the controller 101 to obtain (e.g., pull, receive, etc.) a plurality of voltages (e.g., voltage measurements) of the battery under test 104 from the relay device 102 based on one or more configurations of one or more switches of the relay device 102 in order to determine one or more battery grounds associated with the battery under test 104. For example, the controller 101 may be configured to cause the relay device 102 to enable, or disable, an automated configuration sequence (e.g., automated testing sequence) of the one or more configurations for determining (e.g., measuring) the plurality of voltages, wherein the controller 101 may obtain the plurality of voltages from the relay device 102. In an example, the controller 101 may be configured to control the relay device 102 to implement each configuration of the plurality of configurations according to the automated configuration sequence for determining the plurality of voltages of the battery under test 104. For example, the battery ground measurement program 157 may be implemented to cause the controller 101 to control the relay device 102 to implement each configuration of the plurality of configurations according to the automated configuration sequence for determining the plurality of voltages of the battery under test 104.

The relay device 102 may comprise one or more switches, a power supply, and a voltage monitoring device. In an example, the voltage monitoring device and/or the power supply may be external to the relay device 102 or integrated in the relay device 102 as a single device. The one or more switches may comprise a first switch coupled between a positive bus connection of the battery under test 104 and the voltage monitoring device, a second switch coupled between a first resistor and the voltage monitoring device, a third switch coupled between the voltage monitoring device and a negative bus connection of the battery under test 104, and a fourth switch coupled between the voltage monitoring device and a second resistor. The first resistor may be coupled between the second switch and a ground connection (e.g., earth ground connection). The second resistor may be coupled between the fourth switch and the ground connection.

The controller 101 may cause the relay device 102 to enable, or disable, the automated configuration sequence of the one or more configurations of the one or more switches. As an example, the relay device 102 may implement the automated configuration sequence based on one or more intervals (e.g., every half-hour, every hour, one or more times a day, once a day, once a week, etc.) after receiving a signal from the controller 101 to initiate the automated configuration sequence. After receiving the signal to initiate the automated configuration sequence, the relay device 102 may implement a first configuration of the one or more configurations. The first configuration may comprise closing the first switch and the third switch and opening the second switch and the fourth switch to couple the voltage monitoring device to the positive bus connection and the negative bus connection of the battery under test 104, and thus, completing the connection between the voltage monitoring device to the positive bus connection and the negative bus connection. Based on the first configuration, the relay device 102 may measure a first voltage (e.g., determine a value of the first voltage) associated with the battery under test 104. The first voltage may comprise a battery voltage. For example, the first configuration may enable the relay device 102 to measure a voltage potential difference between the positive bus connection and the negative bus connection. After determining the first voltage, the relay device 102 may reset by causing the first switch and the third switch to open.

Next, the relay device 102 may implement a second configuration of the one or more configurations. The second configuration may comprise closing the first switch and the second switch and opening the third switch and the fourth switch to couple the voltage monitoring device to the positive bus connection of the battery under test 104 and a first resistor, and thus, completing the connection of the voltage monitoring device between the positive bus connection and a ground (e.g., earth ground) with the first resistor in parallel. Based on the second configuration, the relay device 102 may measure a second voltage (e.g., determine a value of the second voltage) associated with the battery under test 104. The second voltage may comprise a positive bus to ground voltage of the battery under test 104. For example, the second configuration may enable the relay device 102 to measure a voltage potential difference between the positive bus connection and the ground via the first resistor in parallel. After determining the second voltage, the relay device 102 may reset causing the first switch and the second switch to open.

Next, the relay device 102 may implement a third configuration of the one or more configurations. The third configuration may comprise closing the third switch and the fourth switch and opening the first switch and the second switch to couple the voltage monitoring device to the negative bus connection of the battery under test 104 and a second resistor, and thus, completing the connection of the voltage monitoring device between the negative bus connection and the ground with the second resistor in parallel. Based on the third connection, the relay device 102 may measure a third voltage associated with the battery under test 104. The third voltage may comprise a ground to negative bus voltage of the battery under test 104. For example, the third configuration may enable the relay device 102 to measure a voltage potential difference between the negative bus connection and the ground via the second resistor in parallel. After determining the third voltage, the relay device 102 may reset by causing the third switch and the fourth switch to open.

The relay device 102 may send data indicative of the value of the first voltage, the value of the second voltage, and the value of the third voltage to the controller 101. The controller 101 may calculate a value of a first resistance and a value of a second resistance associated with the battery under test 104 based on the value of the first voltage, the value of the second voltage, and the value of the third voltage. The values of the first resistance and the second resistance may be used to determine/detect whether a battery ground exists for the battery under test 104. For example, based on the value of the first resistance and/or the value of the second resistance satisfying a threshold, a battery ground may be detected for the battery under test 104. For example, if the value of the first resistance and/or the value of the second resistance are below a threshold resistance value (e.g., ohms), it is determined that a battery ground exists for the battery under test 104. Based on determining the battery ground associated with the battery under test 104, the controller 101 may output one or more notifications. For example, the controller 101 may output a first notification associated with the value of the first resistance satisfying the threshold resistance value and/or a second notification associated with the value of the second resistance satisfying the threshold resistance value. In an example, the controller may output the first notification and/or the second notification to the relay device 102, the server 106, and/or the electronic device 108.

The input/output interface 160 may include an interface for delivering an instruction or data input from a user (e.g., an operator of the controller 101) or from a different external device (e.g., electronic devices 108) to the different elements of the controller 101. Further, the input/output interface 160 may output an instruction or data received from one or more elements of the controller 101 to one or more external devices (e.g., relay device 102 and/or electronic devices 108).

The communication interface 180 may establish, for example, communication between the computing device 101 and one or more external devices (e.g., the relay device 102, the electronic devices 108, or the server 106). In an example, the communication interface 180 may communicate with one or more of the external devices (e.g., the relay device 102, the electronic devices 108, and/or the server 106) by being connected to a network 162 through wireless communication or wired communication. The network 162 may include, for example, at least one of a telecommunications network, a computer network (e.g., LAN or WAN), the Internet, and/or a telephone network.

The communication interface 180 may be configured to communicate with one or more of the external devices (e.g., the sensor devices 102, the display device 104, and/or the output devices 109) via a wired communication interface 164 or a wireless communication interface 164. In an example, the wired communication may include, for example, at least one of Universal Serial Bus (USB), High Definition Multimedia Interface (HDMI), Recommended Standard-232 (RS-232), power-line communication, Plain Old Telephone Service (POTS), and the like. In an example, as a cellular communication protocol, the wireless communication interface 164 may use at least one of Long-Term Evolution (LTE), LTE Advance (LTE-A), Code Division Multiple Access (CDMA), Wideband CDMA (WCDMA), Universal Mobile Telecommunications System (UMTS), Wireless Broadband (WiBro), Global System for Mobile Communications (GSM), and the like. In an example, the wireless communication interface 164 may be configured to use a near-distance communication 164. The near-distance communication interface 164 may include for example, at least one of Wireless Fidelity (WiFi), Bluetooth, Bluetooth Low Energy (BLE), Near Field Communication (NFC), Global Navigation Satellite System (GNSS), and the like. According to a usage region or a bandwidth or the like, the GNSS may include, for example, at least one of Global Positioning System (GPS), Global Navigation Satellite System (GLONASS), BeiDou Navigation Satellite System (BDS), Galileo, the European global satellite-based navigation system, and the like. Hereinafter, the “GPS” and the “GNSS” may be used interchangeably in the present document. In an example, the communication interface 180 may include or be communicably coupled to a transmitter, receiver and/or transceiver for communication with one or more of the external devices (e.g., the relay device 102, the electronic devices 108, or the server 106).

The display device 170 may comprise one or more of a television, an audio/video monitor, a streaming device, and the like. The display device 170 may include various types of displays, for example, a Liquid Crystal Display (LCD) display, a Light Emitting Diode (LED) display, an Organic Light-Emitting Diode (OLED) display, a MicroElectroMechanical Systems (MEMS) display, or an electronic paper display. In an example, the display device 170 may be configured as a part of the controller 101 or as a separate external device in communication with the controller 101 via the communication interface 180. In an example, the display device 170 may include audio output devices (e.g., speakers) for outputting audio signals. In an example, the display device 170 may be in communication with earphones (e.g., noise canceling earphones) so that when audio is played after receiving an alert notification, a single user is alerted audibly instead of playing the audio via the display device's 170 speakers. In an example, the controller 101 may output the one or more notifications associated with the battery ground determination to the display device 170. The display device 170 may display the one or more notifications.

The electronic device 108 may comprise a user device such as a mobile device, a smart phone, a tablet computer, a desktop computer, and the like. In an example, the controller 101 may output the one or more notifications associated with the battery ground determination to the electronic device 108. The electronic device 108 may display the one or more notifications. In an example, the controller 101 may be configured to be remotely operated via the electronic device 108. For example, the electronic device 108 may output one or more commands to operate the controller 101 to implement the battery ground testing process as discussed above.

The server 106 may include a group of one or more servers. For example, all or some of the operations executed by the controller 101 may be executed in a different one or a plurality of electronic devices (e.g., the relay device 102, the electronic devices 108, and/or the server 106). In an example, if the controller 101 needs to perform a certain function or service either automatically or based on a request, the controller 101 may request at least some parts of functions related thereto alternatively or additionally to a different electronic device (e.g., the relay device 102, the electronic devices 108, and/or the server 106) instead of executing the function or the service autonomously. The different electronic devices (e.g., the relay device 102, the electronic devices 108, and/or the server 106) may execute the requested function or additional function, and may deliver a result thereof to the controller 101. The controller 101 may provide the requested function or service either directly or by additionally processing the received result. For example, a cloud computing, distributed computing, or client-server computing technique may be used. In an example, the controller 101 may output the voltage measurements and the resistance calculations to the server 106. The server 106 may store the voltage measurements and the resistance calculations in a database that may be accessed by an external device (e.g., the electronic device 108).

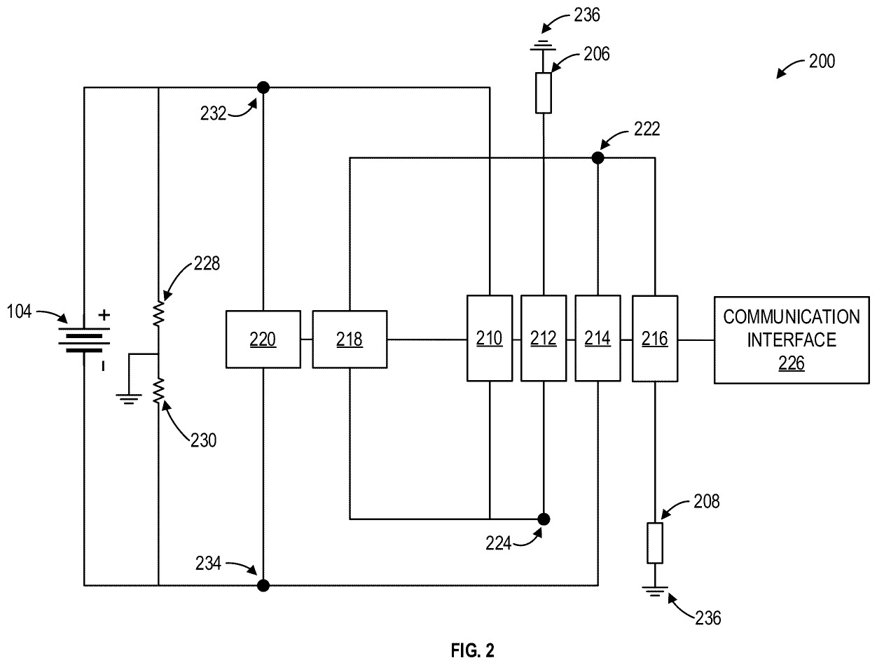

FIG. 2 shows an example configuration 200 of a relay device (e.g., relay device 102). The relay device 102 may comprise a first resistor 206, a second resistor 208, one or more switches 210, 212, 214, 216, a voltage monitoring device 218, a power supply 220, and a communication interface 226. In an example, the first resistor 206, the second resistor 208, the voltage monitoring device 218, and/or the power supply 220 may be external to the relay device 102 or integrated in the relay device 102 as a single device. The relay device 102 may be configured to measure a plurality of voltages associated with a battery under test 104 based on one or more configurations of the one or more switches 210, 212, 214, 216 of the relay device 102 in order to calculate resistance values (e.g., for resistances 228 and 230) associated with a battery under test 104 and determine whether a battery ground exists for the battery under test 104. The power supply 220 may be configured to supply power during the automated configuration sequence (e.g., automated testing sequence). As an example, a controller (e.g., controller 101, computing device, etc.) may be configured to cause the relay device 102 to enable, or disable, an automated configuration sequence of the one or more configurations of the one or more switches 210, 212, 214, 216 for determining (e.g., measuring) the plurality of voltages.

The one or more switches 210, 212, 214, 216 may comprise a first switch 210 coupled between a positive bus connection 232 of the battery under test 104 and the voltage monitoring device 218 (e.g., via connection 222), a second switch 212 coupled between a first resistor 206 and the voltage monitoring device 218 (e.g., via connection 224), a third switch 214 coupled between the voltage monitoring device 218 (e.g., via connection 222) and a negative bus connection 234 of the battery under test 104, and a fourth switch 216 coupled between the voltage monitoring device 218 (e.g., via connection 224) and a second resistor 208. In addition, the first switch 210 may be coupled with the second switch 212 via the connection 222 with the voltage monitoring device 218 and the third switch 214 may be coupled with the fourth switch 216 via the connection 224 with the voltage monitoring device 218. The first resistor 206 may be coupled between the second switch 208 and a ground connection 236 (e.g., earth ground connection). The second resistor 208 may be coupled between the fourth switch 216 and the ground connection 236.

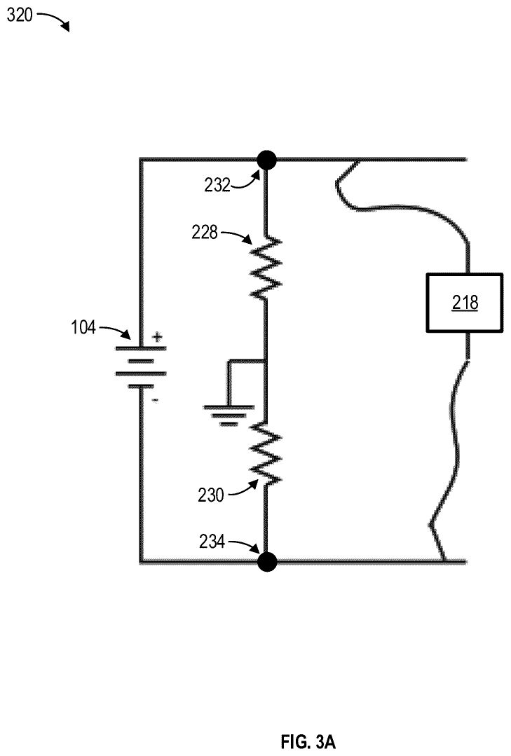

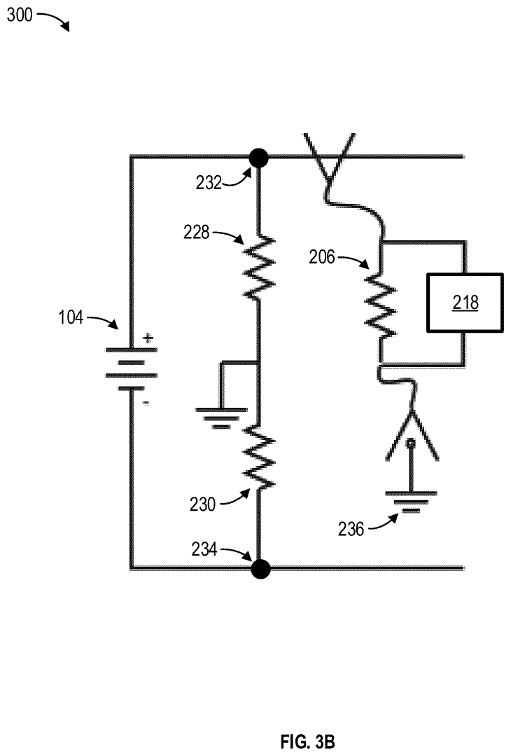

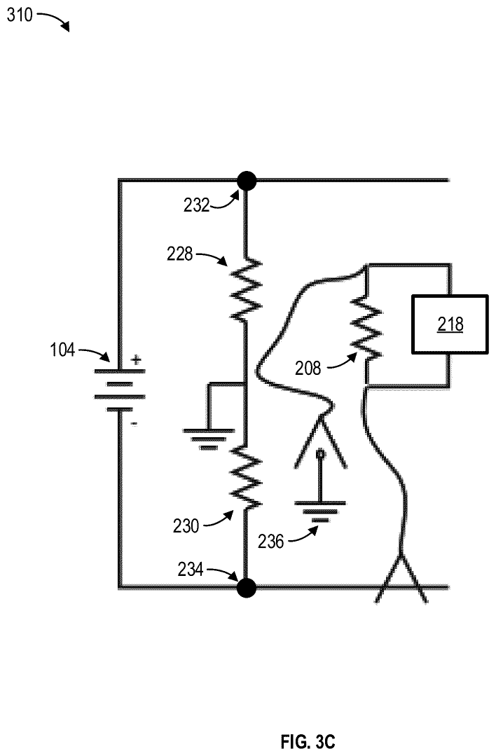

The controller, via the communication interface 226, may cause the relay device 102 to enable, or disable, the automated configuration sequence (e.g., automated testing sequence) of the one or more configurations of the one or more switches 210, 212, 214, 216. As an example, the relay device 102 may implement the automated configuration sequence based on one or more intervals (e.g., every half-hour, every hour, one or more times a day, once a day, once a week, etc.) after receiving a signal from the controller to initiate the automated configuration sequence. After receiving the signal to initiate the automated configuration sequence, the relay device 102 may implement a first configuration of the one or more configurations. The first configuration may comprise closing the first switch 210 and the third switch 214 and opening the second switch 212 and the fourth switch 216 to couple the voltage monitoring device 218 to the positive bus connection 232 and the negative bus connection 234 of the battery under test 104, and thus, completing the connection between the voltage monitoring device 218 to the positive bus connection 232 and the negative bus connection 234. As an example, the first configuration of the relay device 102 may be configured to complete the circuit as shown in FIG. 3A. FIG. 3A shows an example of the first configuration for measuring a first voltage associated with the battery under test 104. Based on the first configuration, the relay device 102 may measure the first voltage (e.g., determine a value of the first voltage) associated with the battery under test 104. The first voltage may comprise a battery voltage (V_{PN}) of the battery under test 104. For example, the first configuration may enable the relay device 102 to measure a voltage potential difference between the positive bus connection 232 and the negative bus connection 234. After determining the first voltage, the relay device 102 may reset by causing the first switch 210 and the third switch 214 to open.

Next, the relay device 102 may implement a second configuration of the one or more configurations. The second configuration may comprise closing the first switch 210 and the second switch 214 and opening the third switch 214 and the fourth switch 216 to couple the voltage monitoring device 218 to the positive bus connection 232 and the first resistor 206, and thus, completing the connection of the voltage monitoring device 218 between the positive bus connection 232 and the ground connection 236 (e.g., earth ground connection) with the first resistor 206 in parallel. As an example, the second configuration of the relay device 102 may be configured to complete the circuit as shown in FIG. 3B. FIG. 3B shows an example of the second configuration for measuring a second voltage associated with the battery under test 104. Based on the second configuration, the relay device 102 may measure the second voltage (e.g., determine a value of the second voltage) associated with the battery under test 104, via the first resistor 206. The second voltage may comprise a positive bus to ground voltage (V_{PG}) of the battery under test 104. For example, the second configuration may enable the relay device 102 to measure a voltage potential difference between the positive bus connection 232 and the ground connection 236 via the first resistor 206 in parallel. After determining the second voltage, the relay device 102 may reset causing the first switch 210 and the second switch 212 to open.

Next, the relay device 102 may implement a third configuration of the one or more configurations. The third configuration may comprise closing the third switch 214 and the fourth switch 216 and opening the first switch 210 and the second switch 212 to couple the voltage monitoring device 218 to the negative bus connection 234 of the battery under test 104 and a second resistor 208, and thus, completing the connection of the voltage monitoring device 218 between the negative bus connection 234 and the ground connection 234 with the second resistor 208 in parallel. As an example, the third configuration of the relay device 102 may be configured to complete the circuit as shown in FIG. 3C. FIG. 3C shows an example of the third configuration for measuring a third voltage associated with the battery under test 104. Based on the third configuration, the relay device 102 may measure the third voltage (e.g., determine a value of the third voltage) associated with the battery under test 104. The third voltage may comprise a ground to negative bus voltage (V_{GN}) of the battery under test 104. For example, the third configuration may enable the relay device 102 to measure a voltage potential difference between the negative bus connection 234 and the ground connection 236 via the second resistor 208 in parallel. After determining the third voltage, the relay device 102 may reset by causing the third switch 214 and the fourth switch 216 open.

The relay device 102 may send data indicative of the value of the first voltage, the value of the second voltage, and the value of the third voltage to the controller 101. The controller 101 may calculate a value of a first resistance 228 (R_{PG}) and a value of a second resistance 230 (R_{NG}) associated with the battery under test 104 based on the value of the first voltage (V_{PN}), the value of the second voltage (V_{PG}), and the value of the third voltage (V_{GN}). For example, R_{PG}=(Test Resistance*(V_{PN}−V_{PG})/V_{GN})−Test Resistance and R_{NG}=(Test Resistance*(V_{PN}−V_{GN})/V_{PG})−Test Resistance. The Test Resistance=Interface Test Box Resistance (e.g., resistances of the first resistor 206 and the second resistor 208, such as 200 k ohms, 300 k ohms, etc.). The values of the first resistance 228 (R_{PG}) and the second resistance 230 (R_{NG}) may be used to determine/detect whether a battery ground occurred with respect to the battery under test 104. For example, based on the value of the first resistance 228 (R_{PG}) and/or the value of the second resistance 230 (R_{NG}) satisfying a threshold, a battery ground may be detected for the battery under test 104. For example, if the value of the first resistance 228 (R_{PG}) and/or the value of the second resistance 230 (R_{NG}) are below a threshold resistance value (e.g., ohms), it is determined that there is battery ground associated with the battery under test 104. Based on determining the battery ground associated with the battery under test 104, the controller 101 may output one or more notifications. For example, the controller 101 may output a first notification associated with the value of the first resistance 228 (R_{PG}) satisfying the threshold resistance value and/or a second notification associated with the value of the second resistance 230 (R_{NG}) satisfying the threshold resistance value. In an example, the controller may output the first notification and/or the second notification to the relay device 102, the server 106, and/or the electronic device 108.

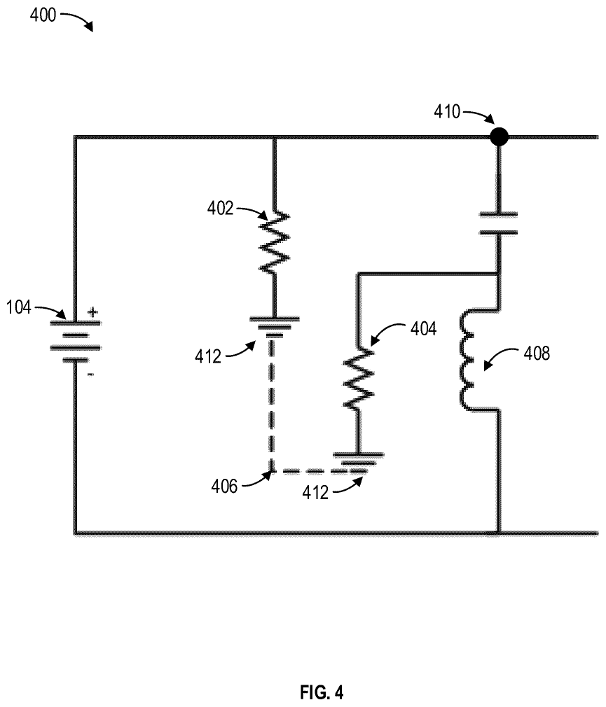

FIG. 4 shows an example battery ground scenario 400. In the example battery ground scenario 400, a first battery ground 402 and a second battery ground 404 may occur. For example, each battery ground 402, 404 may comprise battery grounds of 50 ohms. The lead between the contact and the relay coil 408 may develop the second battery ground 404 of 50 ohms. This may cause a low resistance path 406 between a battery positive bus 410 and the relay coil 408 through earth ground 412. Since the battery grounds 402, 404 are below the threshold resistance value, the relay coil 408 may energize and cause a misoperation (e.g., opening a 345 kV circuit breaker). The battery grounds 402, 404 may be detected based on the automated testing sequence implemented by the controller 101 and the relay device 102, and thus, may be subsequently removed to prevent future misoperations.

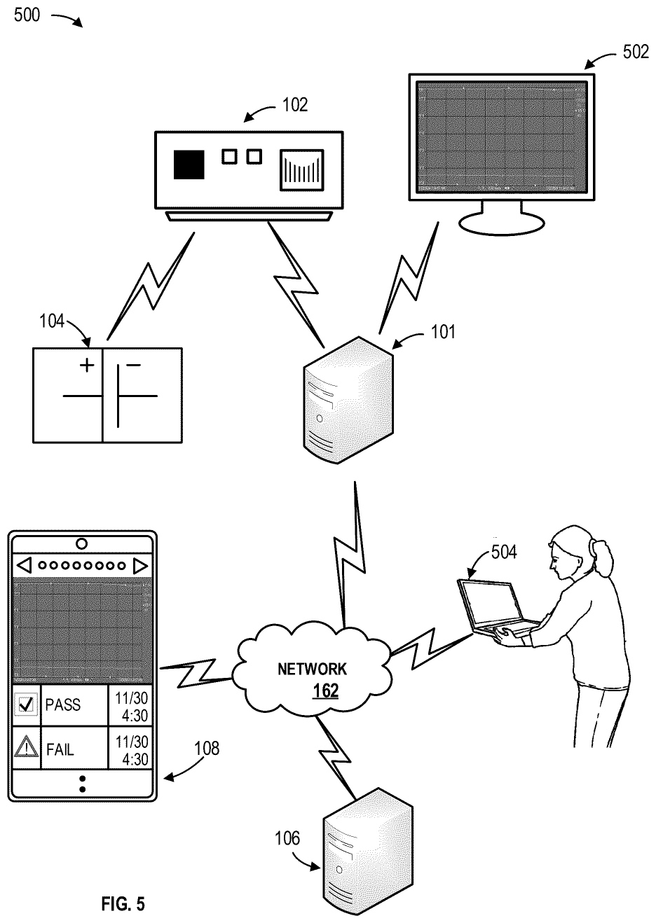

FIG. 5 shows an example system environment 500. The system 500 may comprise the controller 101, the relay device 102, a battery under test 104, the server 106, the electronic device 108, a display device 502, and a remote computing device 504. The controller 101 may be communication with the server 106, the electronic device 108, and the remote computing device 504 via network 162. In addition, the controller 101 may be in communication with the relay device 102 and the display device 502 via a short-range connection (e.g., wired connection, Bluetooth, near-field communicate (NFC), etc.). The controller 101 may be configured to cause the relay device 102 to enable, or disable, an automated configuration sequence (e.g., automated testing sequence) of the one or more configurations of one or more switches of the relay device 102 in order to measure a plurality of voltages of a battery under test 104, wherein the controller 101 may obtain the plurality of voltages from the relay device 102. For example, the relay device 102 may implement the automated configuration sequence based on one or more intervals (e.g., every half-hour, every hour, one or more times a day, once a day, once a week, etc.) after receiving a signal from the controller 101 to initiate the automated configuration sequence. For example, the relay device 102 may measure a first voltage associated with the battery under test 104 based on a first configuration of the one or more switches, a second voltage associated with the battery under test 104 based on a second configuration of the one or more switches, and a third voltage associated with the battery under test 104 based on a third configuration of the one or more switches. The relay device 102 may calculate values of a first resistance and a second resistance associated with the battery under test 104 based on a value of the first voltage, a value of the second voltage, and a value of the second voltage. Based on at least one of the values of the first resistance and the second resistance satisfying a threshold resistance value, the controller 101 may output at least one notification. For example, the controller 101 may output the at least one notification to the relay device 102, the server 106, the electronic device 108, the display device 502, and/or the remote computing device 504. The electronic device 108, the display device 502, and/or the remote computing device 504 may display the at least one notification to a user. In an example, the controller 101 may output the voltage measurements and the resistance calculations to the server 106. The server 106 may store the voltage measurements and the resistance calculations in a database that may be accessed by an external device (e.g., the electronic device 108 and/or the remote computing device 504). In an example, the electronic device 108 and/or the remote computing device 504 (e.g., a mobile device, a smart phone, a tablet computer, a desktop computer, and the like) may be configured to output one or more commands to remotely operate the controller 101 to cause the controller 101 to cause the relay device 102 to enable, or disable, the automated configuration sequence of the one or more configurations of the one or more switches for measuring the plurality of voltages.

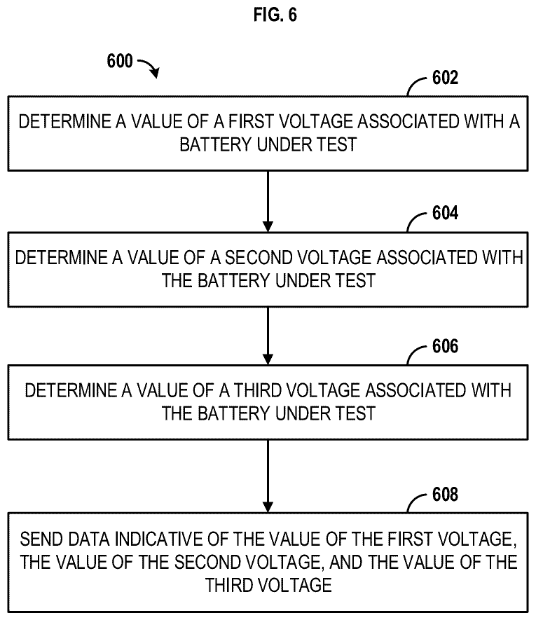

FIG. 6 shows a flowchart of an example method 600 for determining a plurality of voltages associated with a battery under test based on one or more configurations of a relay device and determining resistances associated with the battery under test based on the plurality of voltages in order to determine whether there is a battery ground associated with the battery under test. Method 600 may be implemented, for example, by the controller 101, the relay device 102, the electronic device 108, and/or the server 106, or any combinations thereof. At step 602, a value of a first voltage associated with a battery under test may be determined based on a first configuration of one or more switches of the relay device coupled to a battery under test. For example, the relay device 102 may determine the value of the first voltage associated with the battery under test based on the first configuration of the one or more switches of the relay device coupled to the battery under test. The first configuration may comprise closing a first switch of the one or more switches and a third switch of the one or more switches and opening a second switch of the one or more switches and a fourth switch of the one or more switches to couple the voltage monitoring device to a positive bus connection of the battery under test and a negative bus connection of the battery under test for measuring the first voltage. The first voltage may comprise a battery voltage of the battery under test. For example, the first configuration may enable the relay device 102 to measure a voltage potential difference between the positive bus connection and the negative bus connection. In an example, after determining the first voltage, the relay device 102 may reset by causing the first switch and the third switch to open.

In an example, the relay device 102 may further comprise a voltage monitoring device and one or more resistors coupled between at least one switch of the one or more switches and a ground connection. As an example, the voltage monitoring device may be configured to measure the first voltage, the second voltage, and the third voltage.

At step 604, a value of a second voltage associated with the battery under test may be determined based on a second configuration of the one or more switches. For example, the relay device 102 may determine the value of the second voltage associated with the battery under test based on the second configuration of the one or more switches. The second configuration may comprise closing a first switch of the one or more switches and a second switch of the one or more switches and opening a third switch of the one or more switches and a fourth switch of the one or more switches to couple the voltage monitoring device to a negative bus connection of the battery under test and a resistor of the one or more resistors for measuring the second voltage. The second voltage may comprise a positive bus to ground voltage of the battery under test. For example, the second configuration may enable the relay device 102 to measure a voltage potential difference between the positive bus connection and the ground connection via a first resistor, of the one or more resistors, in parallel. In an example, after determining the second voltage, the relay device 102 may reset causing the first switch and the second switch to open.

At step 606, a value of a third voltage associated with the battery under test may be determined based on a third configuration of the one or more switches. For example, the relay device 102 may determine the value of the third voltage associated with the battery under test based on the third configuration of the one or more switches. The third configuration may comprise closing a first switch of the one or more switches and a second switch of the one or more switches and opening a third switch of the one or more switches and a fourth switch of the one or more switches to couple the voltage monitoring device to the positive bus connection of the battery under test and a resistor of the one or more resistors for measuring the third voltage. The third voltage may comprise a ground to negative bus voltage. For example, the third configuration may enable the relay device 102 to measure a voltage potential difference between the negative bus connection and the ground connection via a second resistor, of the one or more resistors, in parallel. In an example, after determining the third voltage, the relay device 102 may reset by causing the third switch and the fourth switch open.

At step 608, data indicative of the value of the first voltage, the value of the second voltage, and the value of the third voltage may be sent. For example, the relay device 102 may send the value of the first voltage, the value of the second voltage, and the value of the third voltage to a computing device (e.g., the controller 101, the electronic device 108, and/or the server 106, etc.). As an example, the computing device may output at least one notification based on the value of the first voltage, the value of the second voltage, and the value of the third voltage. For example, the computing device may determine a value of a first resistance associated with the battery under test and a value of a second resistance associated with the battery under test based on the value of the first voltage, the value of the second voltage, and the value of the third voltage. The at least one notification may be associated with at least one of the value of the first resistance or the value of the second resistance indicating a battery ground associated with the battery under test. For example, the computing device may determine the at least one notification based on one of the first resistance or the value of the second resistance satisfying a threshold resistance value (e.g., ohms). In an example, the computing device may send the at least one notification to the relay device 102 and/or another computing device (e.g., the controller 101, the electronic device 108, and/or the server 106, etc.).

As an example, if the value of the first resistance and/or the value of the second resistance are below a threshold resistance value, it is determined that a battery ground exists for the battery under test. Based on determining the battery ground associated with the battery under test, the computing device may output one or more notifications. For example, the computing device may output a first notification associated with the value of the first resistance satisfying the threshold resistance value and/or a second notification associated with the value of the second resistance satisfying the threshold resistance value.

While the methods and systems have been described in connection with specific examples, it is not intended that the scope be limited to the particular embodiments set forth, as the embodiments herein are intended in all respects to be illustrative rather than restrictive.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification.

It will be apparent to those skilled in the art that various modifications and variations can be made without departing from the scope or spirit. Other embodiments will be apparent to those skilled in the art from consideration of the specification and practice disclosed herein. It is intended that the specification and examples be considered as exemplary only, with a true scope and spirit being indicated by the following claims.

What is claimed is:

1. An apparatus comprising:
a relay device comprising one or more switches coupled to a battery under test, wherein the relay device is configured to:
determine, based on a first configuration of the one or more switches, a value of the first voltage associated with the battery under test,
determine, based on a second configuration of the one or more switches, a value of the second voltage associated with the battery under test,
determine, based on a third configuration of the one or more switches, a value of the third voltage associated with the battery under test, and
send data indicative of the value of the first voltage, the value of the second voltage, and the value of the third voltage; and
a controller in communication with the relay device, wherein the controller is configured to:
receive data indicative of the value of the first voltage, the value of the second voltage, and the value of the third voltage,
determine, based on the value of the first voltage and the value of the second voltage and the value of the third voltage, a value of a first resistance associated with the battery under test and a value of a second resistance associated with the battery under test, and
cause, based on at least one of the value of the first resistance or the value of the second resistance, output of at least one notification.

2. The apparatus of claim 1, wherein the relay device further comprises a voltage monitoring device, wherein the voltage monitoring device is configured to measure the first voltage, the second voltage, and the third voltage.

3. The apparatus of claim 2, wherein the relay device further comprises one or more resistors coupled between at least one switch of the one or more switches and a ground connection.

4. The apparatus of claim 3, wherein the first configuration comprises closing a first switch of the one or more switches and a third switch of the one or more switches and opening a second switch of the one or more switches and a fourth switch of the one or more switches to couple the voltage monitoring device to a positive bus connection of the battery under test and a negative bus connection of the battery under test for measuring the first voltage.

5. The apparatus of claim 3, wherein the second configuration comprises closing a first switch of the one or more switches and a second switch of the one or more switches and opening a third switch of the one or more switches and a fourth switch of the one or more switches to couple the voltage monitoring device to a positive bus connection of the battery under test and a resistor of the one or more resistors for measuring the second voltage.

6. The apparatus of claim 3, wherein the third configuration comprises closing a third switch of the one or more switches and a fourth switch of the one or more switches and opening a first switch of the one or more switches and a second switch of the one or more switches to couple the voltage monitoring device to a negative bus connection of the battery under test and a resistor of the one or more resistors for measuring the third voltage.

7. The apparatus of claim 1, wherein the first voltage comprises a battery voltage of the battery under test.

8. The apparatus of claim 1, wherein the second voltage comprises a positive bus to ground voltage of the battery under test.

9. The apparatus of claim 1, wherein the third voltage comprises a ground to negative bus voltage of the battery under test.

10. The apparatus of claim 1, wherein the at least one notification is associated with at least one of the value of the first resistance or the value of the second resistance indicating a battery ground associated with the battery under test.

11. A method comprising:
determining, by a relay device, based on a first configuration of one or more switches of the relay device coupled to a battery under test, a value of a first voltage associated with the battery under test;
determining, based on a second configuration of the one or more switches, a value of a second voltage associated with the battery under test;
determining, based on a third configuration of the one or more switches, a value of a third voltage associated with the battery under test; and
sending, to a computing device, data indicative of the value of the first voltage, the value of the second voltage, and the value of the third voltage, wherein the computing device outputs at least one notification based on the value of the first voltage, the value of the second voltage, and the value of the third voltage.

12. The method of claim 11, wherein the relay device further comprises a voltage monitoring device, wherein the voltage monitoring device is configured to measure the first voltage, the second voltage, and the third voltage.

13. The method of claim 12, wherein the relay device further comprises one or more resistors coupled between at least one switch of the one or more switches and a ground connection.

14. The method of claim 13, wherein the first configuration comprises closing a first switch of the one or more switches and a third switch of the one or more switches and opening a second switch of the one or more switches and a fourth switch of the one or more switches to couple the voltage monitoring device to a positive bus connection of the battery under test and a negative bus connection of the battery under test for measuring the first voltage.

15. The method of claim 13, wherein the second configuration comprises the closing a first switch of the one or more switches and a second switch of the one or more switches and opening a third switch of the one or more switches and a fourth switch of the one or more switches to couple the voltage monitoring device to a negative bus connection of the battery under test and a resistor of the one or more resistors for measuring the second voltage.

16. The method of claim 13, wherein the third configuration comprises closing a first switch of the one or more switches and a second switch of the one or more switches and opening a third switch of the one or more switches and a fourth switch of the one or more switches to couple the voltage monitoring device to the positive bus connection of the battery under test and a resistor of the one or more resistors for measuring the third voltage.

17. The method of claim 11, wherein the first voltage comprises a battery voltage of the battery under test.

18. The method of claim 11, wherein the second voltage comprises a positive bus to ground voltage of the battery under test.

19. The method of claim 11, wherein the third voltage comprises a ground to negative bus voltage of the battery under test.

20. The method of claim 11, wherein the computing device determines a value of a first resistance associated with the battery under test and a value of a second resistance associated with the battery under test based on the value of the first voltage, the value of the second voltage, and the value of the third voltage, wherein the at least one notification is associated with at least one of the value of the first resistance or the value of the second resistance indicating a battery ground associated with the battery under test.
